(19) United States
(12) Patent Application Publication
(10) Pub. No.: US 2025/0328082 A1
(43) Pub. Date: Oct. 23, 2025

(54) APPARATUS AND METHOD FOR MANUFACTURING PATTERN STRUCTURE WITH THREE-DIMENSIONAL PATTERN GEOMETRY BY USING PHOTOREACTIVE POLYMER COMPOSITION, AND PATTERN STRUCTURE MANUFACTURED THEREBY

(71) Applicant: KOREA UNIVERSITY RESEARCH AND BUSINESS FOUNDATION, Seoul (KR)

(72) Inventors: Seung Woo LEE, Seoul (KR); Yong Jun LIM, Pohang-si (KR); Kwang Jin KIM, Seoul (KR); Dong Jae BAEK, Seoul (KR); Hee Ju SON, Seoul (KR)

(73) Assignee: KOREA UNIVERSITY RESEARCH AND BUSINESS FOUNDATION, Seoul (KR)

(21) Appl. No.: 19/212,107

(22) Filed: May 19, 2025

Related U.S. Application Data
(63) Continuation of application No. PCT/KR2023/018706, filed on Nov. 20, 2023.

(30) Foreign Application Priority Data
Nov. 18, 2022 (KR) 10-2022-0155206
Nov. 18, 2022 (KR) 10-2022-0155214
Jan. 26, 2023 (KR) 10-2023-0009891
Nov. 15, 2023 (KR) 10-2023-0158265

(51) Int. Cl. G03F 7/00; G02B 1/00

(52) U.S. Cl. CPC G03F 7/70308; G02B 1/002; G03F 7/001; G03F 7/70291

(57) ABSTRACT

An optical element manufacturing apparatus is disclosed. The optical element manufacturing apparatus may comprise: a light source for generating light; a light modulation device which is provided with the light from the light source, and polarizes and diffracts the light to modulate the light so as to make a spatial change in the intensity of the light; a photoreactive polymer composition which is irradiated with the light modulated by the light modulation device; and a substrate which supports the photoreactive polymer composition.

### TECHNICAL FIELD

The present invention relates to a method for manufacturing a pattern structure having a three-dimensional pattern geometry by using a photoreactive polymer composition, and a pattern structure manufactured thereby.

### BACKGROUND ART

A diffractive grating is one of the oldest optical elements. In the mid-1800s, Joseph von Fraunhofer successfully developed surface gratings, thereby opening up the world of diffraction spectrum analysis. Thereafter, in the late 1890s, Gabriel Lippman proved that a grating may be encoded in a volumetric medium, resulting in the birth of holography.

A hologram recording medium records information by changing a refractive index in the recording medium through an exposure process, and reproduces information by reading the change in the refractive index within the recording medium recorded as described above.

When the photoreactive polymer composition is used as the recording medium, since an optical interference pattern may be easily stored as a hologram by photopolymerization of a low molecular weight monomer, the photoreactive polymer composition may be used in various fields such as an optical lens, a mirror, a deflection mirror, a filter, a diffusion screen, a diffraction member, a light guide, a waveguide, a holographic optical element having a projection screen and/or a mask function, a medium of an optical memory system and a light diffusion plate, an optical wavelength splitter, a reflective color filter, a transmissive color filter, and the like.

In general, a photoreactive polymer composition for hologram production includes a polymer binder (matrix), a monomer, and a photoinitiator, and a photosensitive film manufactured from the composition is irradiated with laser interference light to induce photopolymerization of a local monomer.

In the photopolymerization process, the refractive index increases in a portion where a relatively large amount of monomers are present, and the refractive index relatively decreases in a portion where a relatively large amount of polymer binders are present, so that refractive index modulation occurs, thereby generating diffraction gratings by the refractive index modulation.

Regarding the photoreactive polymer composition, U.S. Pat. No. 4,942,102 (Jul. 17, 1990) discloses a photoreactive polymer composition obtained by using an acryl- and/or vinyl-type monomer, a polymer binder (polyvinyl acetate, polyvinyl acetal, polyvinyl formal, or polyvinyl butyral), a plasticizer, and a photoinitiation system, and U.S. Pat. No. 4,959,284 (Sep. 25, 1990) discloses a photoreactive polymer composition obtained by using a cyclopropane compound contained as a monomer component and cyclopentanone 2,5-bis {[4-(diethyl amino)phenyl]methylene} (DEAW), which is a compound known as a dye-sensitizer.

### DISCLOSURE

### Technical Problem

One technical problem to be solved by the present invention is to provide an apparatus and a method for manufacturing a pattern structure having a three-dimensional pattern geometry by using a photoreactive polymer composition, and a pattern structure manufactured thereby.

Another technical problem to be solved by the present invention is to provide a pattern structure which diffracts irradiated light to generate an optical signal and a method for manufacturing the same.

Still another technical problem to be solved by the present invention is to provide a photoreactive polymer composition that may be used in manufacturing a hologram and an optical recording medium including the same.

Still another technical problem to be solved by the present invention is to provide a photoreactive polymer composition having high photosensitivity and an optical recording medium including the same.

Still another technical problem to be solved by the present invention is to provide a photoreactive polymer composition with an improved monomer diffusion rate and an optical recording medium including the same.

Still another technical problem to be solved by the present invention is to provide a photoreactive polymer composition with an improved recording speed and an optical recording medium including the same.

Still another technical problem to be solved by the present invention is to provide a photoreactive polymer composition having with improved recording efficiency and an optical recording medium including the same.

Still another technical problem to be solved by the present invention is to provide a pattern structure with improved diffraction efficiency and a method for manufacturing the same.

Still another technical problem to be solved by the present invention is to provide a pattern structure capable of improving diffraction efficiency by controlling light irradiated to a photoreactive polymer composition, and a method for manufacturing the same.

Still another technical problem to be solved by the present invention is to provide a pattern structure capable of improving diffraction efficiency by controlling a thickness, and a method for manufacturing the same.

Still another technical problem to be solved by the present invention is to provide a pattern structure capable of improving diffraction efficiency by controlling a refractive index modulation value, and a method for manufacturing the same.

The technical problems to be solved by the present invention are not limited to those described above.

### Technical Solution

To solve the above technical problems, the present invention provides an apparatus for manufacturing a pattern structure.

According to one embodiment, the apparatus for manufacturing the pattern structure may include: a light source for generating light; a light modulation element configured to receive the light from the light source and polarize and diffract the light to modulate the light such that a spatial change in intensity may be formed; a photoreactive polymer composition irradiated with the light modulated by the light modulation element; and a substrate configured to support the photoreactive polymer composition.

According to one embodiment, the modulated light may have a three-dimensional spatial change in intensity within a volume range.

According to one embodiment, the light modulation element may include a meta-surface mask.

According to one embodiment, the light generated from the light source may have a three-dimensional spatial change in intensity within a volume range as the light is transmitted through the meta-surface mask.

According to one embodiment, the photoreactive polymer composition irradiated with the modulated light may have a three-dimensional spatial change in physical properties within a volume range.

According to one embodiment, the photoreactive polymer composition may include at least one of a polymer matrix, a monomer, and a photoinitiator.

According to one embodiment, the modulated light may be irradiated to one region of the photoreactive polymer composition, and a difference in physical properties may be present between a first region of the photoreactive polymer composition, which is irradiated with the modulated light, and a second region of the photoreactive polymer composition, which is not irradiated with the modulated light.

According to one embodiment, in the photoreactive polymer composition in which the modulated light is irradiated to the first region between the first and second regions, the monomer may be diffused from the second region to the first region.

According to one embodiment, the first region may be formed with a polymerized polymer by the monomer so that a difference in a content of the polymerized polymer may be present between the first region and the second region.

According to one embodiment, the polymer matrix may remain in the second region as the monomer is diffused from the second region to the first region, so that a difference in a density of the polymerized polymer due to the monomer is present between the first region and the second region.

According to one embodiment, the difference in the physical properties may be present between the first region and the second region as the differences in the content and the density of the polymerized polymer occur between the first region and the second region, or a degree of arrangement of molecules varies depending on polarization.

To solve the above technical problems, the present invention provides a method for manufacturing a pattern structure.

According to one embodiment, the method for manufacturing a pattern structure may include: generating light from a light source; providing the light generated from the light source to the light modulation element to modulate the light by polarizing and diffracting the light such that a spatial change in intensity is formed; and irradiating a photoreactive polymer composition disposed on a substrate with the modulated light such that a spatial change in physical properties is three-dimensionally formed within a volume range of the photoreactive polymer composition.

According to one embodiment, the modulating of the light may include modulating the light such that the spatial change in intensity is three-dimensionally formed within the volume range.

According to one embodiment, the modulated light may be irradiated to one region of the photoreactive polymer composition disposed on the substrate, and a first region of the photoreactive polymer composition, which is irradiated with the modulated light, and a second region of the photoreactive polymer composition, which is not irradiated with the modulated light, may extend upward from a top surface of the substrate.

### Advantageous Effects

The apparatus for manufacturing the pattern structure according to the embodiment of the present invention may include: a light source for generating light; a light modulation element configured to receive the light from the light source and polarize and diffract the light to modulate the light such that a spatial change in intensity is formed; and an optical recording medium including a photoreactive polymer composition irradiated with the light modulated by the light modulation element, and a substrate configured to support the photoreactive polymer composition. Accordingly, a pattern structure in which a spatial change in physical properties is formed three-dimensionally within a volume range may be easily manufactured.

### DESCRIPTION OF DRAWINGS

FIGS. 1 and 2 are schematic configuration views of an apparatus for manufacturing an optical element according to an embodiment of the present invention.

FIG. 3 is a view illustrating one example of a meta-surface mask that may be used as a light modulation element.

FIG. 4 is a view for explaining a first region, which is irradiated with light, and a second region, which is not irradiated with light, in a photoreactive polymer composition.

FIGS. 5 and 6 are views for explaining a difference in physical properties between the first region, which is irradiated with light, and the second region, which is not irradiated with light, in the photoreactive polymer composition.

FIG. 7 is a view for explaining a process of manufacturing a polymer matrix of the photoreactive polymer composition according to the embodiment of the present invention.

FIG. 8 is a view for explaining a process of activating a photoinitiator of the photoreactive polymer composition according to the embodiment of the present invention.

FIG. 9 is a view for explaining a difference between an optical element formed by irradiating light having a sinusoidal waveform and an optical element formed by irradiating light having a binary waveform.

FIG. 10 is a view for explaining a difference between an optical signal generated though the optical element formed by irradiating light having a sinusoidal waveform and an optical signal generated through the optical element formed by irradiating light having a binary waveform.

FIGS. 11 and 12 are views for explaining an influence of a difference in a refractive index between the first region and the second region of the optical element on diffraction efficiency of the optical element.

FIG. 13 is a view for explaining a difference in diffraction efficiency generated in optical elements having mutually different thicknesses.

FIG. 14 is a view comparing a diffraction efficiency full width at half maximum of a 10 μm-thick optical element with a diffraction efficiency full width at half maximum of a 60 μm-thick optical element.

FIG. 15 is a view for explaining a change in a path of diffracted light that moves according to a change in a thickness of the optical element.

FIG. 16 is a view comparing diffraction efficiency of the 10 μm-thick optical element with diffraction efficiency of the 60 μm-thick optical element.

FIG. 17 is a view for explaining a relationship between the thickness the optical element and the refractive index modulation value.

### MODE FOR INVENTION

Hereinafter, preferred embodiments of the present invention will be described in detail with reference to the accompanying drawings. However, the present invention may be embodied in different forms and should not be construed as limited to the embodiments set forth herein. Rather, the embodiments are provided so that this disclosure will be thorough and complete, and will fully convey the scope of the present invention to those skilled in the art.

In the present specification, it will be understood that when an element is referred to as being “on” another element, it can be formed directly on the other element or intervening elements may be present. In the drawings, the thicknesses of layers and regions are exaggerated for clarity.

In addition, it will be also understood that although the terms first, second, third, etc. may be used herein to describe various elements, these elements should not be limited by these terms. These terms are only used to distinguish one element from another element. Thus, a first element in some embodiments may be termed a second element in other embodiments without departing from the teachings of the present invention. Embodiments explained and illustrated herein include their complementary counterparts. As used herein, the term “and/or” includes any and all combinations of one or more of the associated listed elements.

The singular expression also includes the plural meaning as long as it does not differently mean in the context. In addition, the terms “comprise”, “have” etc., of the description are used to indicate that there are features, numbers, steps, elements, or combinations thereof, and they should not exclude the possibilities of combination or addition of one or more features, numbers, operations, elements, or a combination thereof. Furthermore, it will be understood that when an element is referred to as being “connected” or “coupled” to another element, it may be directly connected or coupled to the other element or intervening elements may be present.

In addition, when detailed descriptions of related known functions or constitutions are considered to unnecessarily cloud the gist of the present invention in describing the present invention below, the detailed descriptions will not be included. In addition, in the following description of the present invention, the term “optical element” is used in the same meaning as “pattern structure”.

### Apparatus and Method for Manufacturing Optical Element According to Embodiment

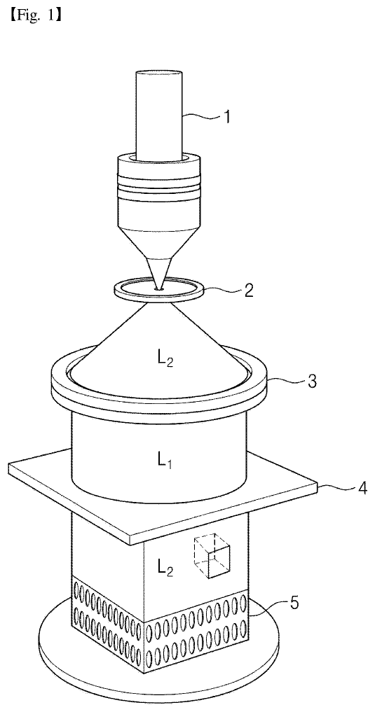

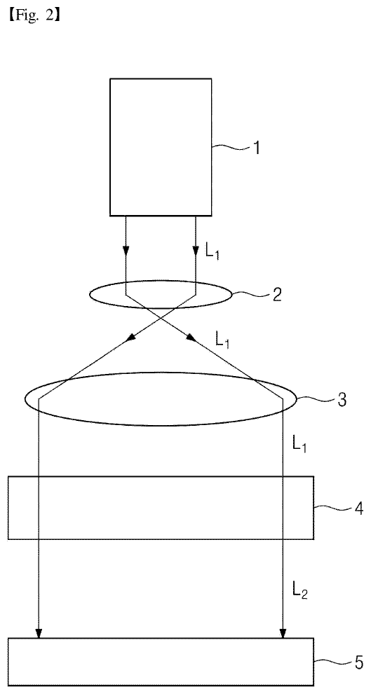

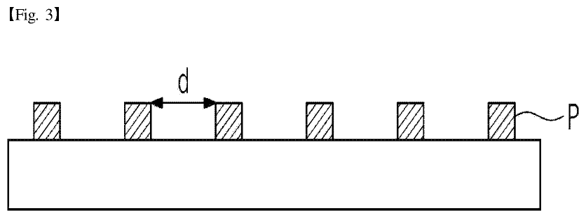

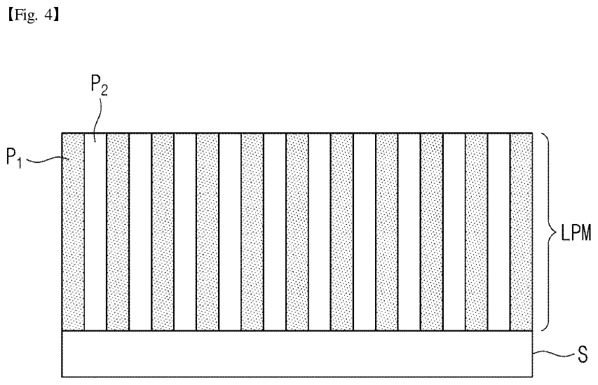

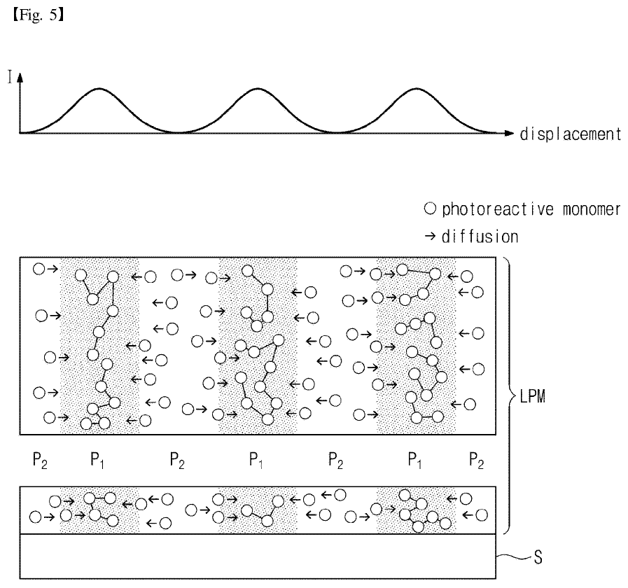

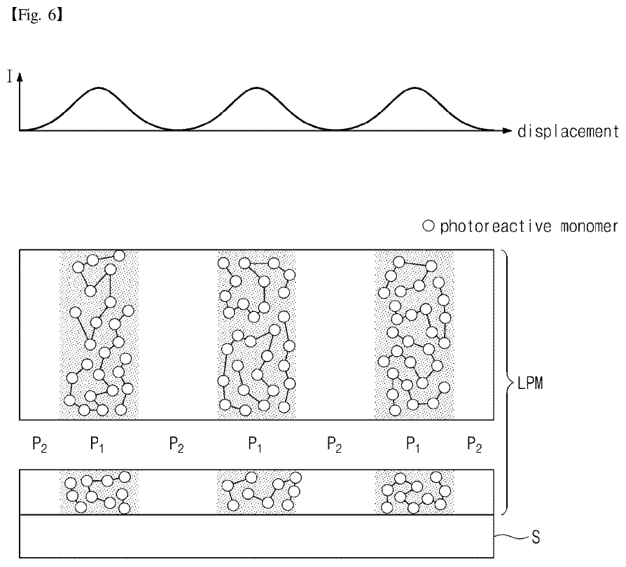

FIGS. 1 and 2 are schematic configuration views of an apparatus for manufacturing an optical element according to an embodiment of the present invention, FIG. 3 is a view illustrating one example of a meta-surface mask that may be used as a light modulation element, FIG. 4 is a view for explaining a first region, which is irradiated with light, and a second region, which is not irradiated with light, in a photoreactive polymer composition, and FIGS. 5 and 6 are views for explaining a difference in physical properties between the first region, which is irradiated with light, and the second region, which is not irradiated with light, in the photoreactive polymer composition.

Referring to FIGS. 1 and 2, the apparatus for manufacturing an optical element may include a light source 1, a first lens 2, a second lens 3, an optical modulation element 4, and an optical recording medium 5. The above-described apparatus is an example of an apparatus for manufacturing an optical structure, and some of the above-described components may be omitted or other components other than the above-described components may be further included.

The light source 1 is for generating light, and according to one embodiment, the light source 1 may generate laser light that is coherent single light.

The first lens 2 and the second lens 3 may be arranged in a direction in which light L₁ generated from the light source 1 is irradiated. The first lens 2 and the second lens 3 may transmit the light L₁ generated from the light source 1. According to one embodiment, the light L₁ generated from the light source 1 may be transmitted through the second lens 3 after being transmitted through the first lens 2. In addition, the first lens 2 and the second lens 3 are beam expanders and may enlarge the size of the light L₁ generated from the light source 1. According to one embodiment, the first lens 2 and the second lens 3 may be omitted. However, when the first lens 2 and the second lens 3 are omitted, it may be difficult to manufacture a large-area optical element finally generated. That is, the first lens 2 and the second lens 3 are disposed in a direction in which the light L₁ generated from the light source 1 is irradiated to enlarge a size of the light L₁ generated from the light source 1, so that it is possible to more easily manufacture the large-area optical structure finally generated.

The light L₁ transmitted through the first lens 2 and the second lens 3 may be provided to the light modulation device 4. The light L₁ provided to the light modulation device 4 may be transmitted through the light modulation device 4, and transmitted light L₂ may be modulated by the light modulation device 4. According to one embodiment, the light modulation element 4 forms a spatial change in intensity by polarizing and/or diffracting the light L₁, and examples thereof may include a photomask, a phase modulation mask, a meta-surface mask, a diffraction grating, and the like, but the present invention is not limited thereto. According to one embodiment, the light modulation element 4 may generate diffracted light beams having mutually different orders (e.g., 0^{th} order, +1^{st} order, −1^{st} order, etc.) for the incident light L₁, and may generate light L₂ having a three-dimensional pattern geometry (a geometry in which a spatial change in intensity is three-dimensionally arranged within a volume range of light) through interference of the generated diffracted light beams. That is, the light L₁ may be transmitted through the light modulation element 4 to be modulated into the light L₂ having a three-dimensional pattern geometry.

Referring to FIG. 3, an example of a meta-surface mask that may be used as the light modulation element 4 is illustrated. As illustrated in FIG. 3, the meta-surface mask may include a base substrate and a pattern structure spaced apart from each other on the base substrate, and the light L₁ transmitted through the meta-surface mask may be modulated into the light L₂ having a three-dimensional pattern geometry.

According to one embodiment, a distance d between a patterns P of the pattern structure and a wavelength A of the light L₁ irradiated to the light modulation element 4 may satisfy the following <Equation 1>.

$$d \leq 0.9 \times λ \qquad < Equation 1 >$$

When <Equation 1> is satisfied, structures (meta-atoms) of spatially different shapes may be arranged to independently control phase and diffraction according to positions, and a degree of freedom in spatial arrangement of each meta-atom is high, so that a more complex 3D interference pattern than the following <Equation 2> may be generated.

$$d > 0.9 \times λ \qquad < Equation 2 >$$

On the other hand, when <Equation 2> is satisfied, diffraction and phase are controlled together through repetition of the same structure, and when a degree of freedom in design is lower than <Equation 1> and a period is greater than 0.9 times the wavelength, a limited 3D interference pattern may be generated.

According to one embodiment, the pattern structure of the meta-surface mask may be formed of at least one of silicon, silica (SiO₂), TiO₂, quartz, Ge, GaAs, or Au, and the base substrate may be formed of at least one of glass, SiO₂, TiO₂, quartz, or a transparent polymer.

Referring to FIGS. 4 to 6, the light L₂ modulated through the light modulation element 4 may be provided to the optical recording medium 5. According to one embodiment, the optical recording medium may include a substrate S and a photoreactive polymer composition LPM provided on the substrate S. According to one embodiment, the photoreactive polymer composition LPM may include a polymer matrix, a monomer, and a photoinitiator.

The modulated light L₂ may be irradiated to one region of the photoreactive polymer composition LPM. A region that is irradiated with the modulated light L₂ is referred to as a first region P₁, and a region that is not irradiated with the modulated light L₂ is referred to as a second region P₂. According to one embodiment, the modulated light L₂ may be irradiated to the photoreactive polymer composition LPM such that the first region P₁ and the second region P₂ are alternately and repeatedly arranged side by side.

When the modulated light L₂ is irradiated to one region of the photoreactive polymer composition LPM, the monomers (photoreactive monomers) of the photoreactive polymer composition LPM may be diffused from the second region P₂ to the first region P₁ thereby forming a polymerized polymer by the monomers. Accordingly, a content of the polymerized polymer may be relatively increased in the first region P₁ within the photoreactive polymer composition LPM, and thus a difference in the content of the polymerized polymer may be present between the first region P₁ and the second region P₂. Alternatively, a polymer matrix of the photoreactive polymer composition LPM may remain in the second region P₂, and thus a difference in density of the composition may be present between the first region P₁ and the second region P₂. Accordingly, a difference in physical properties (e.g., refractive index, dielectric constant, porosity, composition, density, etc.) may be formed between the first region P₁ and the second region P₂. That is, as the differences in the content and density of the polymerized polymer occur between the first region P₁ and the second region P₂, the difference in physical properties (e.g., refractive index, dielectric constant, porosity, composition, density, etc.) may be formed between the first region P₁ and the second region P₂. The photoreactive polymer composition LPM having the difference in physical properties between the first region P₁ irradiated with light and the second region P₂ not irradiated with light may be defined as an optical element. The optical element may diffract the irradiated light to generate an optical signal.

In addition, as described above, when the modulated light L₂ has a three-dimensional pattern geometry, since the three-dimensional pattern geometry of the modulated light L₂ may be reflected in the photoreactive polymer composition LPM, the three-dimensional pattern geometry (a geometry having a three-dimensional spatial change in physical properties within a volume range) may be recorded in the first region P₁ irradiated with the modulated light L₂. That is, the photoreactive polymer composition LPM irradiated with the modulated light L₂ may have the three-dimensional spatial change in physical properties within the volume range.

Hereinabove, the apparatus and method for manufacturing an optical element according to the embodiment of the present invention has been described. Hereinafter, a photoreactive polymer composition used in a manufacturing process of the optical element according to the embodiment of the present invention will be described in more detail.

### Photoreactive Polymer Composition According to Embodiment

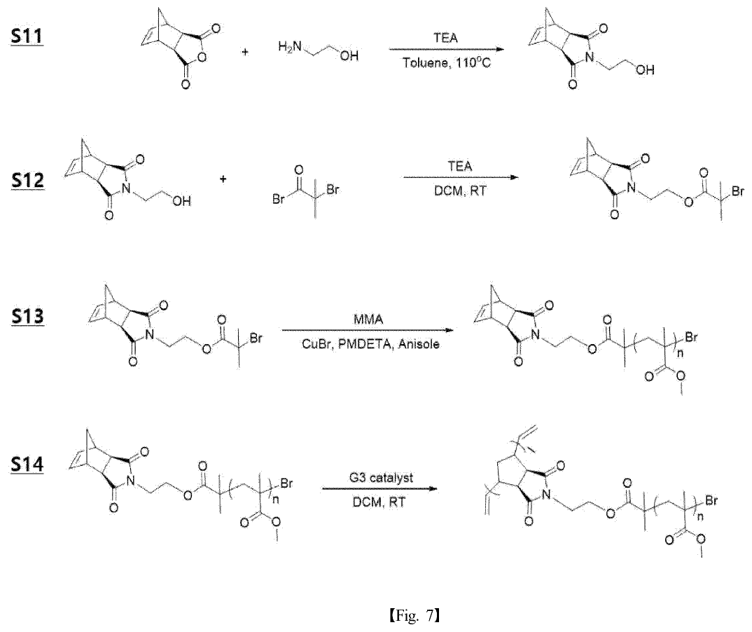

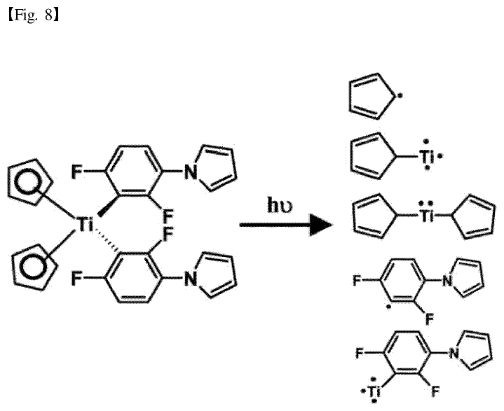

FIG. 7 is a view for explaining a process of manufacturing a polymer matrix of the photoreactive polymer composition according to the embodiment of the present invention, and FIG. 8 is a view for explaining a process of activating a photoinitiator of the photoreactive polymer composition according to the embodiment of the present invention.

The photoreactive polymer composition according to the embodiment of the present invention may include a polymer matrix, a monomer, a photoinitiator, a solvent, and nanoparticles. According to one embodiment, based on the total weight of the photoreactive polymer composition, the polymer matrix may be included in an amount of 20 wt %, the monomer may be included in an amount of 16 wt % or greater and 18 wt % or less, the photoinitiator may be included in an amount of 2 wt % or greater and 4 wt % or less, and the solvent may be included in an amount of 60 wt %, but the present invention is not limited to the above-described composition.

The polymer matrix may include a copolymer of a first block forming a main chain and a second block forming a side chain. According to one embodiment, the first block may include a first polymer having a relatively large molecular weight. More specifically, the first polymer may include a polymer having a degree of polymerization (DP) of less than 300. For example, the first polymer may include poly-norbornene (PNB). In contrast, the second block may include a second polymer having a relatively small molecular weight. More specifically, the second polymer may include a polymer having a DP lower than that of the first polymer. For example, the second polymer may include poly(methyl methacrylate) (PMMA). Although PNB has been exemplarily described as the first polymer and PMMA has been exemplarily described as the second polymer, various polymers in which the first block forming a main chain and the second block forming a side branch may form a copolymer may be used as the first polymer and the second polymer. That is, the type of polymer that may be used as the first polymer of the first block and the second polymer of the second block is not limited. However, unlike the above description, when a polymer having a DP of 300 or greater is used as the first polymer, there may be a problem in that a polymer film is not properly formed. In addition, when a polymer having a DP higher than the first polymer is used as the second polymer, there may be a problem in that the polymer matrix is entangled.

As described above, when the first polymer includes PNB and the second polymer includes PMMA, the polymer matrix may include a graft copolymer (PNB-g-PMMA) of PNB and PMMA, and the polymer matrix may be represented by the following <Chemical Formula 1>. In this case, the first block may be defined as a block including a compound represented by A in <Chemical Formula 1>, and the second block may be defined as a block including a compound represented by B in <Chemical Formula 2>.

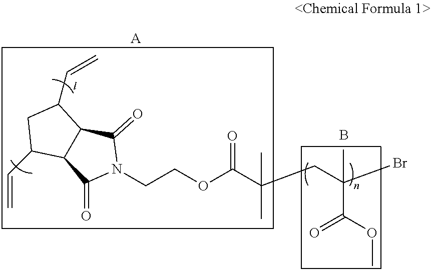

According to one embodiment, as illustrated in FIG. 7, the polymer matrix may be prepared through: a step S11 of mixing a compound represented by <Chemical Formula 3> and a compound represented by <Chemical Formula 4> with tetraethylammonium (TEA) and toluene, and heat-treating the mixture at 110° C. to form a first intermediate represented by <Chemical Formula 5>; a step S12 of mixing the first intermediate and a compound represented by <Chemical Formula 6> with tetraethylammonium (TEA) and dichloromethane (DCM) at room temperature RT to form a second intermediate represented by <Chemical Formula 7>; a step S13 of mixing the second intermediate with methyl methacrylate (MMA), copper (I) bromide (Cubr), N, N,N′,N″, N″-pentamethyldiethylenetriamine (PMDETA), and anisole to form a third intermediate represented by <Chemical Formula 8>; and a step S14 of mixing the third intermediate with a G3 catalyst and dichloromethane (DCM) at room temperature RT. <Chemical Formula 3> to <Chemical Formula>8 are as follows.

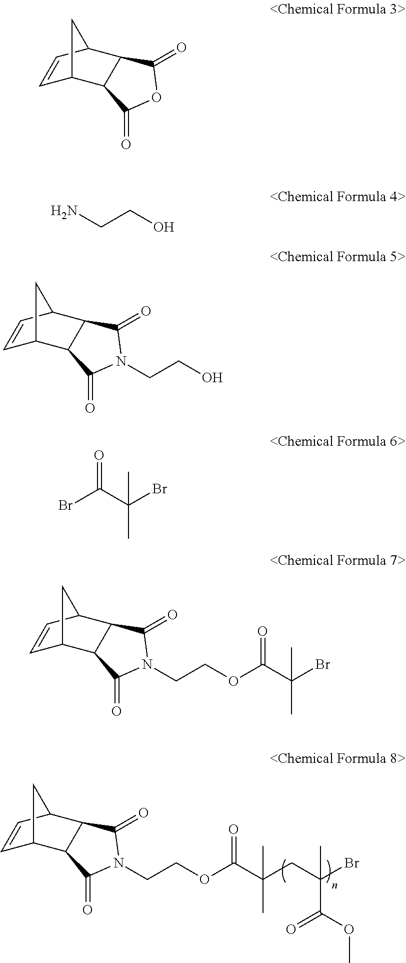

As described above, when the copolymer of the first block forming the main chain and the second block forming the side branch (e.g., PNB-g-PMMA) is used as the polymer matrix, a monomer diffusion rate of the photoreactive polymer composition may be improved compared to the case where a linear polymer (e.g., linear PMMA) is used as the polymer matrix. Accordingly, a recording speed and recording efficiency using the photoreactive polymer composition may be significantly improved.

The monomer is a material that enables radical polymerization, and in a photopolymerization process, the refractive index may be relatively increased in a region where a relatively large number of polymerized polymers are formed by the monomer, and the refractive index may be relatively decreased in a region where a relatively large number of polymer matrices are formed, thereby generating refractive index modulation and generating diffraction gratings by the refractive index modulation.

According to one embodiment, the monomer may have a refractive index of 1.4 to 1.6. In contrast, when the monomer has a refractive index other than the above-described refractive index, there is a problem in that the function as a hologram is lost because the recorded medium is not properly diffracted when a structure for the purpose of the hologram is recorded.

According to one embodiment, the monomer may include any one of acrylate and acrylamide. For example, benzyl methacrylate (BZMA) represented by <Chemical Formula 9> may be used as the monomer. In contrast, as another example, the monomer may include a (meth)acrylate-based α,β-unsaturated carboxylic acid derivative, specifically, (meth)acrylate, (meth)acrylamide, (meth)acrylonitrile, (meth)acrylic acid, or the like, or a compound including a vinyl group or a thiol group, but the present invention is not limited thereto.

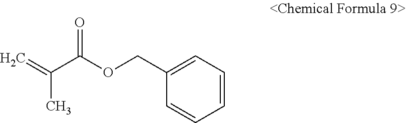

The photoinitiator is a compound activated by light, and may initiate polymerization of a compound containing a photoreactive functional group such as the monomer. According to one embodiment, the photoinitiator may include a dye, a photoinitiator, or a combination thereof, which absorbs light to generate radicals. In contrast, according to another embodiment, the photoinitiator may include a photoradical polymerization initiator. In contrast, according to still another embodiment, the photoinitiator may include a photocationic polymerization initiator or a photoanionic polymerization initiator. For example, as the photoinitiator, Irgacure represented by the following <Chemical Formula 10> may be used, and in this case, an activity reaction by light may occur as illustrated in FIG. 2. In addition, methylorange, methyleneblue, and the like may be used as the photoinitiator, but the present invention is not limited thereto.

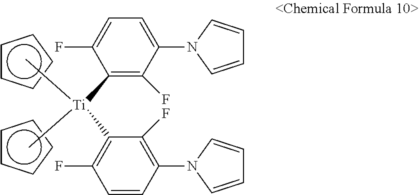

The solvent is for dispersing the above-described components (polymer matrix, monomer, and photoinitiator), and according to one embodiment, ketones, alcohols, acetates, ethers, and the like may be used. For example, as the solvent, a ketone such as methylethylketone, methylisobutylketone, acetylacetone, or isobutylketone, an alcohol such as methanol, ethanol, n-propanol, i-propanol, n-butanol, i-butanol, or t-butanol, an acetate such as ethyl acetate, i-propyl acetate, or polyethylene glycol monomethylether acetate, an ether such as tetrahydrofuran or propylene glycol monomethylether, or a mixture of two or more thereof may be used.

Hereinabove, the photoreactive polymer composition according to the embodiment of the present invention has been described. Hereinafter, a method for improving diffraction efficiency of an optical element according to the embodiment of the present invention will be described.

### Method for Improving Diffraction Efficiency of Optical Element According to Embodiment

In the present invention, in order to improve diffraction efficiency of the optical element, a waveform of the light L₂ irradiated to the photoreactive polymer composition LPM may be controlled. Specifically, the light L₂ irradiated to the photoreactive polymer composition LPM is controlled to have a sinusoidal waveform, so that the diffraction efficiency of the optical element may be improved. In addition, according to the present invention, the diffraction efficiency of the optical element may be improved by using a thickness of the optical element and a difference in a refractive index between the first region P₁ and the second region P₂.

Hereinafter, an influence of the waveform of the light L₂ irradiated to the photoreactive polymer composition LPM on the diffraction efficiency of the optical element will be described first.

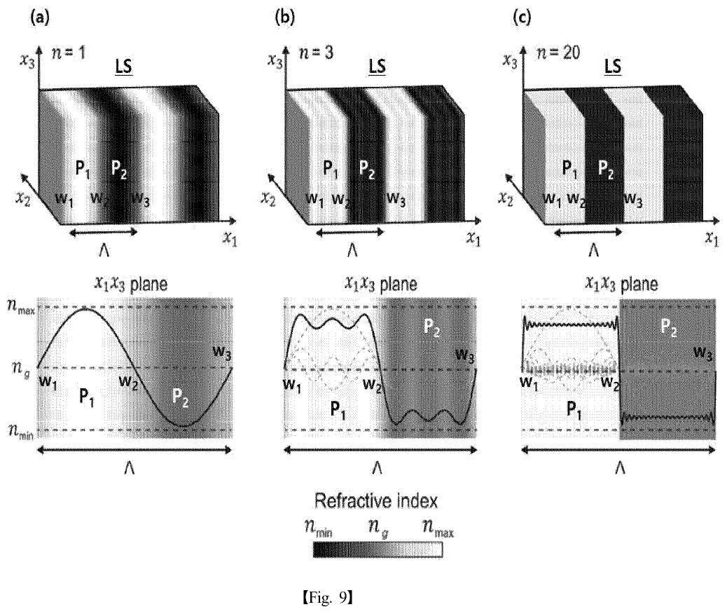

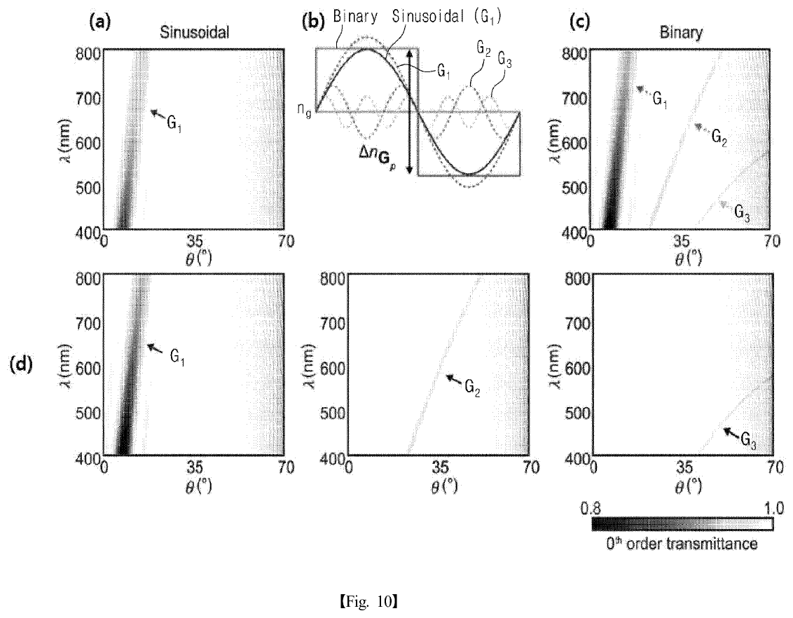

FIG. 9 is a view for explaining a difference between an optical element formed by irradiating light having a sinusoidal waveform and an optical element formed by irradiating light having a binary waveform, and FIG. 10 is a view for explaining a difference between an optical signal generated though the optical element formed by irradiating light having a sinusoidal waveform and an optical signal generated through the optical element formed by irradiating light having a binary waveform.

A binary waveform refers to a waveform in which a plurality of sinusoidal waveforms having mutually different frequencies are combined, and FIG. 9(a) illustrates an optical element LS formed by irradiation of light having a sinusoidal waveform with a single frequency, FIG. 9(b) illustrates an optical element LS formed by irradiation of light having a binary waveform in which three sinusoidal waveforms are combined, and FIG. 9(c) illustrates an optical element LS formed by irradiation of light having a binary waveform in which 20 sinusoidal waveforms are combined.

FIG. 10(a) illustrates an optical signal generated by the optical element described in FIG. 9(a), FIG. 10(c) illustrates an optical signal generated by the optical element described in FIG. 9(b), FIG. 10(d) illustrates G₁, G₂, and G₃ illustrated in FIG. 10(c), and FIG. 10(b) illustrates a refractive index profile shown in a grating period Λ of the optical element described in FIG. 10(a) and a refractive index profile shown in the grating period Λ of the optical element described in FIG. 9(b).

As illustrated in FIG. 9(a), the optical element LS formed by irradiation of light having a sinusoidal waveform with a single frequency may have a refractive index gradient in a form in which a refractive index gradually increases and decreases, and then increases again from the first region P₁ to the second region P₂ within a grating period Λ defined by the first region P₁ and the second region P₂ adjacent to each other. More specifically, the first region P₁ within the grating period Λ may have a refractive index gradient such that the refractive index gradually increases from a side wall w₁ far from the second region P₂ toward a side wall w₂ adjacent to the second region P₂ based on an effective refractive index n_{g} so as to have a maximum refractive index nₘₐₓ, and then gradually decreases to the effective refractive index n_{g}. In contrast, the second region P₂ within the grating period Λ may have a refractive index gradient such that the refractive index gradually decreases from the side wall w₂ adjacent to the first region P₁ to a side wall w₃ far from the first region P₁ so as to have a minimum refractive index nₘᵢₙ, and then gradually increases to have an effective refractive index n_{g}.

When an optical signal is generated through the optical element having the refractive index gradient as illustrated in FIG. 9(a), as illustrated in FIGS. 10(a) and 10(b), since light diffracted through the optical element moves through a single path G₁, optical loss may be significantly reduced, and thus the diffraction efficiency of the optical element may be improved.

In contrast, as illustrated in FIGS. 9(b) and 9(c), the optical element LS formed by irradiation of light having a binary waveform may have a refractive index gradient in a direction from the first region P₁ to the second region P₂ within the grating period Λ that is defined by the first region P₁ and the second region P₂ adjacent to each other, and may also have a region in which the refractive index is maintained substantially constant (a region in which an increase or decrease of the refractive index is slightly repeated). More specifically, the first region P₁ within the grating period Λ may have a refractive index gradient such that the refractive index rapidly increases from the side wall w₁ far from the second region P₂ toward the side wall w₂ adjacent to the second region P₂ based on the effective refractive index n_{g} so as to maintain the increased state, and then rapidly decreases to the effective refractive index. In contrast, the second region P₂ within the grating period Λ may have a refractive index gradient such that the refractive index rapidly decreases from the side wall w₂ adjacent to the first region P₁ to the side wall w₃ far from the first region P₁ so as to maintain the decreased state, and then rapidly increases to the effective refractive index. In particular, as illustrated in FIG. 9(c), as the binary waveform is combined with a larger number of sinusoidal waveforms, a range of a region in which the refractive index is maintained substantially constant may increase, and the deviation of the refractive index in the region in which the refractive index is maintained substantially constant may also be significantly reduced.

When an optical signal is generated through the optical element having the refractive index gradient as illustrated in FIGS. 9(b) and 9(c), as illustrated in FIGS. 10(b) to 10(d), light diffracted through the optical element moves through a plurality of paths G₁, G₂, and G₃, so that optical loss may occur, thereby reducing diffraction efficiency of the optical element.

As a result, the optical structure may be manufactured by irradiating the photoreactive polymer composition LPM with light having a sinusoidal waveform, thereby improving the diffraction efficiency of the optical structure. In addition, the optical element formed by irradiating light having a sinusoidal waveform may have a refractive index gradient in the form of a sinusoidal wave within the grating period Λ that is defined by the first region P₁ and the second region P₂ adjacent to each other. That is, the first region P₁ may have a refractive index gradient such that a refractive index of a central portion thereof is higher than a refractive index of an edge region thereof, and the second region P₂ may have a refractive index gradient such that the refractive index of the central portion thereof is lower than the refractive index of the edge region thereof. In addition, the first region P₁ may have a refractive index gradient such that the refractive index gradually increases and decreases from the side wall w₁ far from the second region P₂ toward the side wall w₂ adjacent to the second region P₂ and there is no region in which an increase or decrease in the refractive index is repeated, and the second region P₂ may have a refractive index gradient such that the refractive index gradually decreases and increases from the side wall w₂ adjacent to the first region P₁ toward the side wall w₃ far from the first region P₁ and there is no region in which the increase or decrease in the refractive index is repeated. In addition, the first region P₁ and the second region P₂ may be formed to have the same physical properties in a thickness direction of the optical element. The thickness direction of the optical element may be a direction in which the first region P₁ and the second region P₂ extend, and the direction in which the first region P₁ and the second region P₂ extend may be the same as a direction upward from a top surface of the substrate S.

Hereinabove, the influence of the waveform of light irradiated to the photoreactive polymer composition LPM on the diffraction efficiency of the optical element has been described. Hereinafter, an influence of the thickness of the optical element and the difference in the refractive index between the first region P₁ and the second region P₂ on the diffraction efficiency of the optical element will be described.

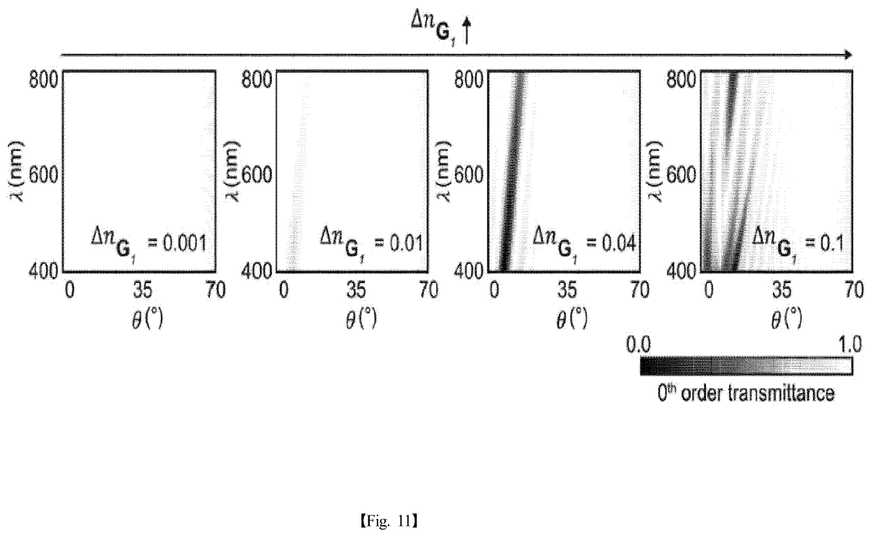

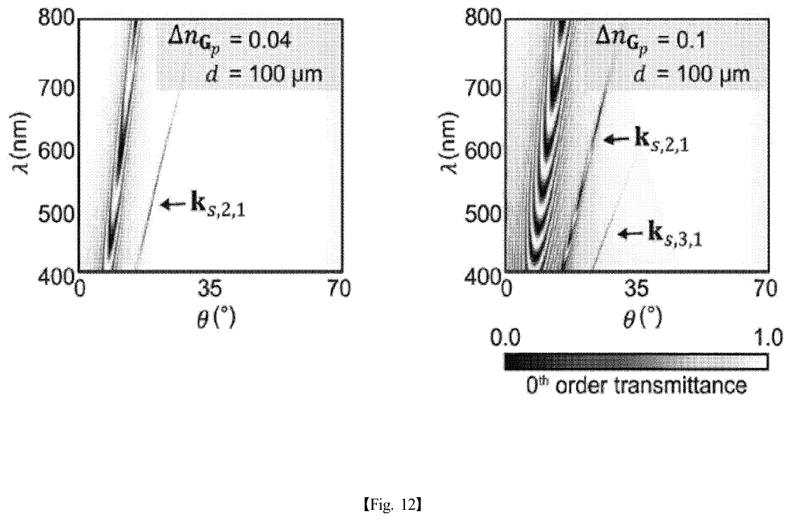

FIGS. 11 and 12 are views for explaining an influence of a difference in a refractive index between the first region and the second region of the optical element on diffraction efficiency of the optical element.

FIG. 11 illustrates a difference between optical signals generated according to a refractive index modulation value (Δn_{G1} or Δn_{Gp}), which is defined as a maximum value of a refractive index difference between the first region P₁ and the second region P₂, that is, a difference value between a maximum refractive index of the first region P₁ and a minimum refractive index of the second region P₂, in a state in which the thickness of the optical element is fixed (d=100 μm), and FIG. 12 illustrates a difference between an optical signal generated at a refractive index modulation value (Δn_{Gp}=0.04) and an optical signal generated at a refractive index modulation value (Δn_{Gp}=0.1).

As can be seen from FIGS. 11 and 12, it can be seen that as the refractive index modulation value (Δn_{Gp}=0.04) increases, the number of paths through which the light diffracted through the optical element moves significantly increases. When the number of paths through which the light diffracted through the optical element moves increases, optical loss increases, so that the diffraction efficiency of the optical element is reduced, and thus it can be seen that the difference in the refractive index between the first region P₁ and the second region P₂ affects the diffraction efficiency of the optical element.

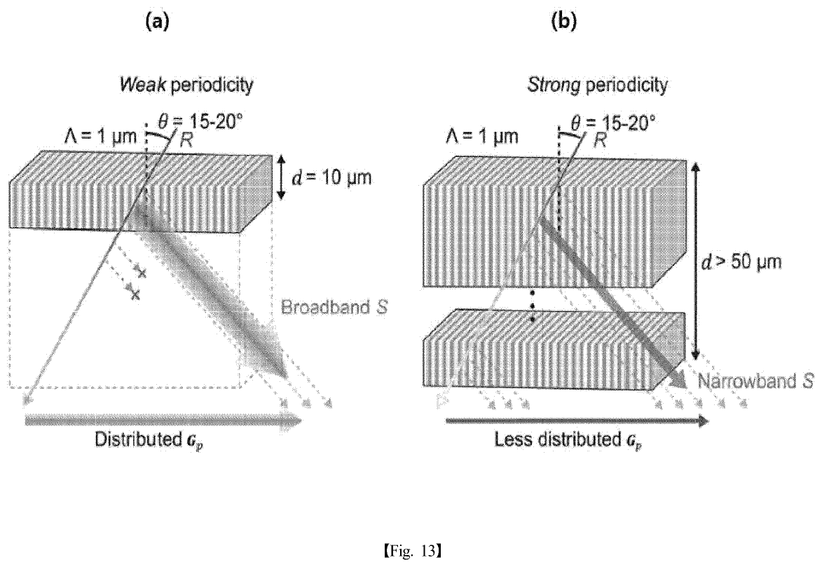

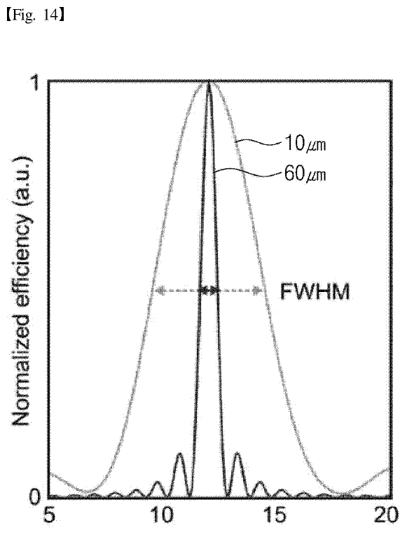

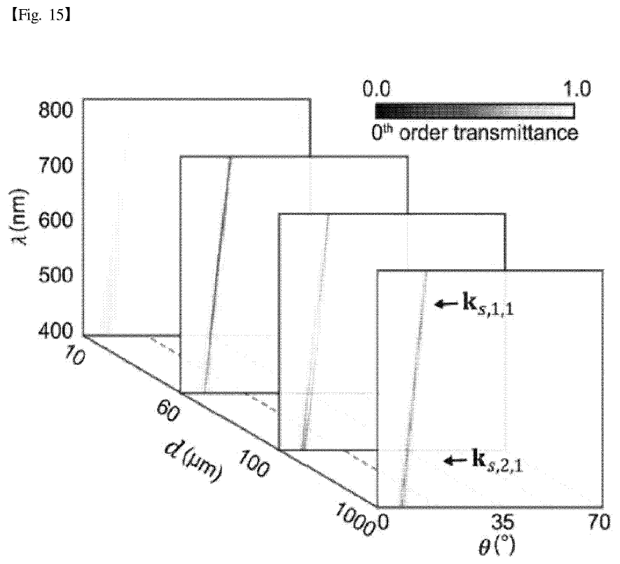

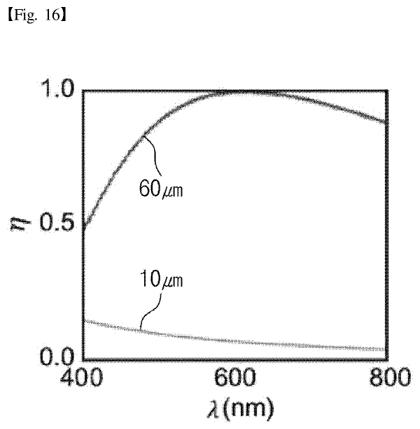

FIG. 13 is a view for explaining a difference in diffraction efficiency generated in optical elements having mutually different thicknesses, FIG. 14 is a view comparing a diffraction efficiency full width at half maximum of a 10 μm-thick optical element with a diffraction efficiency full width at half maximum of a 60 μm-thick optical element, FIG. 15 is a view for explaining a change in a path of diffracted light that moves according to a change in a thickness of the optical element, and FIG. 16 is a view comparing diffraction efficiency of the 10 μm-thick optical element with diffraction efficiency of the 60 μm-thick optical element.

Referring to FIG. 13(a), an optical element having a relatively small thickness (d=10 μm) has a weak periodicity, so that as Gₚ defined by the following <Equation 3> is dispersed, broadband diffracted light S may be formed. Accordingly, since the diffraction efficiency is limited, the diffraction efficiency may be reduced.

In contrast, referring to FIG. 13(b), an optical element having a relatively large thickness (d>50 μm) has a strong periodicity, so that as Gₚ defined by the following <Equation 3> is less distributed, broadband diffracted light S may be formed. Accordingly, since the limitation of diffraction efficiency is eliminated, the diffraction efficiency may be improved.

$${G}_{p} = 2 π / {Λ}_{p} \qquad < Equation 3 >$$

(Λₚ: Grating period defined by first region and second region adjacent to each other)

Referring to FIG. 14, it can be seen that the diffraction efficiency full width at half maximum (FWHM) of the 10 μm-thick optical element is significantly narrower than the diffraction efficiency FWHM of the 10 μm-thick optical element. That is, it can be seen that the diffraction efficiency of the 10 μm-thick optical element has a wide range, whereas the diffraction efficiency of the 60 μm-thick optical element has a narrow range, so that the diffraction efficiency of the 60 μm-thick optical element is improved compared to the 10 μm-thick optical element.

Referring to FIG. 15, it can be seen that the generation of the path through which the diffracted light moves also increases as the thickness of the optical element changes (10 μm to 1000 μm). In particular, since it is confirmed that a plurality of paths are generated at a thickness of 100 μm or greater, it can be seen that optical loss occurs at a thickness of 100 μm or greater, and thus diffraction efficiency of the optical element is reduced.

Referring to FIG. 16, it can be seen that the diffraction efficiency η of the 60 μm-thick optical element is significantly higher than that of the 10 μm-thick optical element.

That is, it can be seen from FIGS. 13 to 16 that not only the refractive index difference between the first region and the second region of the optical element, but also the thickness of the optical element affect the diffraction efficiency of the optical element. Accordingly, the present invention specifically presents a method for improving the diffraction efficiency of the optical element using the difference in the refractive index between the first region and the second region and the thickness of the optical element.

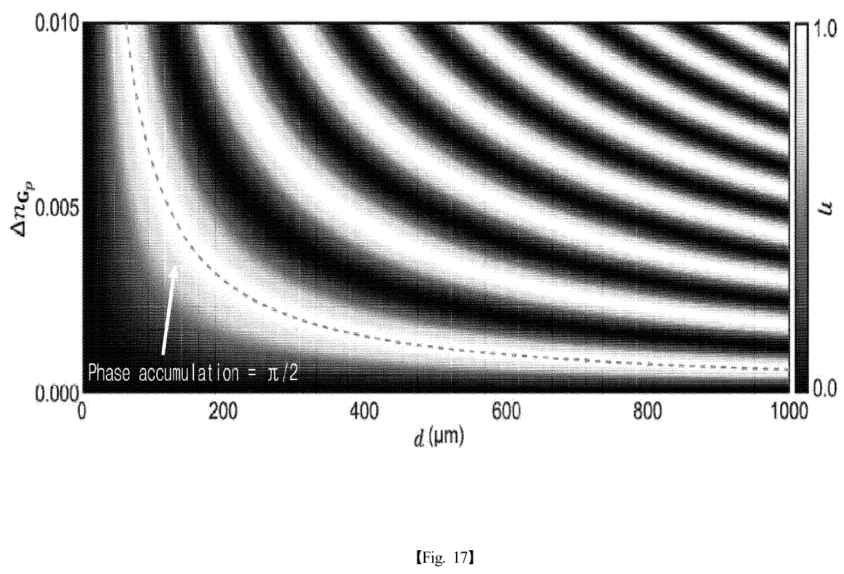

FIG. 17 is a view for explaining a relationship between the thickness of the optical element and the refractive index modulation value.

The relationship between a thickness d of the optical element and the refractive index modulation value Δn_{Gp} may be shown as illustrated in FIG. 17, and accordingly, a method capable of improving the diffraction efficiency of the optical element is derived. Specifically, the diffraction efficiency of the optical element represented by the following <Equation 5> may be derived using phase accumulation represented by the following <Equation 4>, and the diffraction efficiency may be maximized when the phase accumulation represented by <Equation 4> satisfies Π/2.

$$Phase accumulaton = \frac{\frac{1}{2} Δ {n}_{{G}_{p}} d π}{λ cos θ} \qquad < Equation 4 >$$

$$η = {sin}^{2} ( \frac{\frac{1}{2} Δ {n}_{{G}_{p}} d π}{λ cos θ} ) \qquad < Equation 5 >$$

(η: Diffraction efficiency of optical element, Δn_{Gp}: Refractive index modulation value defined as maximum value of difference in refractive index between first region and second region, d: Thickness of optical element, λ: Wavelength of light irradiated to optical element, θ: Angle between normal line of top surface of optical element and light irradiated to optical element)

As can be seen from <Equation 4>, when the wavelength λ of the light irradiated to the optical element and the angle θ between the normal line of the top surface of the optical element and the light irradiated to the optical element are fixed, it can be seen that the phase accumulation is determined by the refractive index modulation value Δn_{Gp} and the thickness d. Accordingly, in manufacturing the optical element, the refractive index modulation value Δn_{Gp} and the thickness d of the optical element may be controlled so that the phase accumulation satisfies Π/2, thereby maximizing the diffraction efficiency of the optical element. In addition, since the optical element with the maximized diffraction efficiency may minimize the influence of unnecessary frequency components in generating the optical signal, only a desired optical signal may be generated.

Hereinabove, the method for improving diffraction efficiency of the optical element according to the embodiment of the present invention has been described. Hereinafter, specific experimental examples for the photoreactive polymer composition according to the embodiment of the present invention will be described.

### Photoreactive Polymer Composition According to Experimental Example and Manufacture of Optical Element Using the Same

An optical element was manufactured by preparing a photoreactive polymer composition according to Experimental Example 3 by mixing a PNB-g-PMMA polymer matrix, a BzMA monomer, an Irgacure-784 photoinitiator, and an anisole solvent, and irradiating the prepared photoreactive polymer composition with light.

The composition of the photoreactive polymer composition according to the experimental example described above was variously changed, and characteristics of the optical element according to the changed composition were evaluated. The evaluated results are summarized in the following Table 1.

TABLE 1

| Classification | Ex 1 | Ex 2 | Ex 3 | Ex 4 | Ex 5 | Ex 6 | Ex 7 | Ex 8 |
|---|---|---|---|---|---|---|---|---|
| PNB-g-PMMA | 19 | 20 | 20 | 20 | 20 | 19 | 29 | 17 |
| (wt %) | | | | | | | | |
| BzMA (wt %) | 19 | 16 | 18 | 19.8 | 19 | 19 | 10 | 30 |
| Irgacure (wt %) | 2 | 4 | 2 | 0.2 | 1 | 2 | 1 | 3 |
| Anisole (wt %) | 60 | 60 | 60 | 60 | 60 | 60 | 60 | 60 |
| Thickness (μm) | 200 | 220 | 220 | 200 | 180 | 25 | 25 | 25 |
| Efficiency (%) | 60 | 82 | 85 | 52 | 39 | 7 | 6 | 9 |

As can be seen from <Table 1>, it can be seen that a significant difference in diffraction efficiency (Efficiency, %) is generated depending on the composition of the photoreactive polymer composition. In particular, it can be seen that high diffraction efficiency of 82% to 85% may be achieved when the composition includes a polymer matrix (PNB-g-PMMA) in an amount of 20 wt %, a monomer in an amount of 16 wt % or greater and 18 wt % or less, a photoinitiator in an amount of 2 wt % or greater and 4 wt % or less, and a solvent in an amount of 60 wt %.

While the present invention has been described in connection with the embodiments, it is not to be limited thereto but will be defined by the appended claims. In addition, it is to be understood that those skilled in the art may substitute, change, or modify the embodiments in various forms without departing from the scope and spirit of the present invention.

### INDUSTRIAL APPLICABILITY

The apparatus and for manufacturing a pattern structure having a three-dimensional pattern geometry by using a photoreactive polymer composition according to the embodiment of the present application, and the pattern structure manufactured thereby may be utilized in various industrial fields such as semiconductors, secondary batteries, displays, photocatalysts, hydrogen, and PUFs.

1. An apparatus for manufacturing a pattern structure, the apparatus comprising:
a light source for generating light;
a light modulation element configured to receive the light from the light source and polarize and diffract the light to modulate the light such that a spatial change in intensity is formed; and
an optical recording medium including a photoreactive polymer composition irradiated with the light modulated by the light modulation element, and a substrate configured to support the photoreactive polymer composition.

2. The apparatus of claim 1, wherein the modulated light has a three-dimensional spatial change in intensity within a volume range.

3. The apparatus of claim 1, wherein the light modulation element includes a meta-surface mask.

4. The apparatus of claim 3, wherein the light generated from the light source has a three-dimensional change in intensity within a volume range as the light is transmitted through the meta-surface mask.

5. The apparatus of claim 1, wherein the photoreactive polymer composition irradiated with the modulated light has a three-dimensional spatial change in physical properties within a volume range.

6. The apparatus of claim 1, wherein the photoreactive polymer composition includes at least one of a polymer matrix, a monomer, and a photoinitiator.

7. The apparatus of claim 6, wherein the modulated light is irradiated to one region of the photoreactive polymer composition, and
a difference in physical properties is present between a first region of the photoreactive polymer composition, which is irradiated with the modulated light, and a second region of the photoreactive polymer composition, which is not irradiated with the modulated light.

8. The apparatus of claim 7, wherein in the photoreactive polymer composition in which the modulated light is irradiated to the first region between the first and second regions, the monomer is diffused from the second region to the first region.

9. The apparatus of claim 8, wherein the first region is formed with a polymerized polymer by the monomer so that a difference in a content of the polymerized polymer is present between the first region and the second region.

10. The apparatus of claim 9, wherein the polymer matrix remains in the second region as the monomer is diffused from the second region to the first region, so that a difference in a density of the polymerized polymer due to the monomer is present between the first region and the second region.

11. The apparatus of claim 10, wherein the difference in the physical properties is present between the first region and the second region as the differences in the content and the density of the polymerized polymer occur between the first region and the second region, or a degree of arrangement of molecules varies depending on polarization.

12. A method for manufacturing a pattern structure, the method comprising:
generating light from a light source;
providing the light generated from the light source to the light modulation element to modulate the light by polarizing and diffracting the light such that a spatial change in intensity is formed; and
irradiating a photoreactive polymer composition disposed on a substrate with the modulated light such that a spatial change in physical properties is three-dimensionally formed within a volume range of the photoreactive polymer composition.

13. The method of claim 12, wherein the modulating of the light includes modulating the light such that the spatial change in intensity is three-dimensionally formed within the volume range.

14. The method of claim 12, wherein the modulated light is irradiated to one region of the photoreactive polymer composition disposed on the substrate, and
a first region of the photoreactive polymer composition, which is irradiated with the modulated light, and a second region of the photoreactive polymer composition, which is not irradiated with the modulated light, extend upward from a top surface of the substrate.
